(19) United States
(12) Patent Application Publication
(10) Pub. No.: US 2025/0350356 A1
(43) Pub. Date: Nov. 13, 2025

(54) OPTOELECTRONIC INTEGRATED CIRCUIT TESTING DEVICES

(71) Applicant: CHUNGHWA PRECISION TEST TECH. CO., LTD., TAOYUAN CITY (TW)

(72) Inventors: Hsun tai WEI, TAOYUAN CITY (TW); Wei cheng WANG, TAOYUAN CITY (TW); Hsiao ching HUNG, TAOYUAN CITY (TW)

(21) Appl. No.: 19/039,720

(22) Filed: Jan. 28, 2025

(30) Foreign Application Priority Data
May 8, 2024 (TW) 113117060

(51) Int. Cl. H04B 10/073; G01M 11/00; G01M 11/02; G01R 31/28

(52) U.S. Cl. CPC H04B 10/073; G01M 11/0207; G01M 11/33; G01R 31/2886

(57) ABSTRACT

An optoelectronic integrated circuit testing device, configured to test optoelectronic integrated circuits, includes an automated testing equipment; an optical fiber connected to the automated testing equipment respectively; a receiving interface module disposed on the automated testing equipment, wherein the receiving interface module is provided with the optical fiber through hole for the optical fiber to pass through; a plurality of probes, wherein each probe is connected to the receiving interface module; and a guide plate module disposed on the receiving interface module, wherein the plurality of probes and the optical fiber pass through the guide plate module. The plurality of probes pressed against the optoelectronic integrated circuit when testing the optoelectronic integrated circuit, and the optical fiber receives optical communication signals transmitted from the optoelectronic integrated circuit.

### CROSS REFERENCE TO RELATED APPLICATIONS

This application claims the benefit of and priority to Taiwan Patent Application No. 113117060, filed May 8, 2024, the entirety of which is hereby incorporated herein by reference.

### FIELD OF INVENTION

The present application relates to an optoelectronic integrated circuit testing device, and more particularly to an optoelectronic integrated circuit testing device that simultaneously measures electrical signals and optical communication signals of the optoelectronic integrated circuit.

### BACKGROUND OF INVENTION

Optoelectronic integrated circuits (OEIC) include photonic integrated circuits and electronic integrated circuits, the OEIC using light for data transmission can break through electrical limitations to meet the communication transmission needs of the new era. However, in optoelectronic integrated circuits, the signal transmission methods of electronic transmission and photon transmission conflict with each other, making it difficult to measure simultaneously. Therefore, there is an urgent need for technical improvements that can integrate photoelectric measurement.

### SUMMARY OF INVENTION

In order to achieve the above purpose, the present application provides an optoelectronic integrated circuit testing device for testing an optoelectronic integrated circuit, including: an automated testing equipment; an optical fiber connected to the automated testing equipment; a receiving interface module disposed on the automated testing equipment, and provided with an optical fiber through hole for the optical fiber to pass through; a plurality of probes, wherein each probe is connected to the receiving interface module; and a guide plate module disposed on the receiving interface module, wherein the plurality of probes and the optical fiber pass through the guide plate module; wherein the plurality of probes pressed against the optoelectronic integrated circuit when testing the optoelectronic integrated circuit, and the optical fiber receives optical communication signals transmitted from the optoelectronic integrated circuit.

In one preferred embodiment of the present application, the guide plate module includes: a first guide plate disposed on the receiving interface module, wherein the first guide plate comprises a plurality of first guide plate through holes for the optical fiber and the plurality of probes to pass through; and a second guide plate disposed on the first guide plate, wherein the second guide plate includes a plurality of second guide plate through holes for the optical fiber and the plurality of probes to pass through.

In one preferred embodiment of the present application, portions where the plurality of probes pass through the guide plate module are respectively provided with a probe elastic portion.

In one preferred embodiment of the present application, the receiving interface module includes: a printed circuit board provided on the automated testing equipment, wherein the printed circuit board is provided with a first optical fiber through hole for the optical fiber to pass through; and a space converter provided on the printed circuit board, wherein the space converter is provided with a second optical fiber through hole for the optical fiber to pass through; wherein each probe connected to the space converter, and each optical fiber through hole includes the first optical fiber through hole and the second optical fiber through hole respectively.

In one preferred embodiment of the present application, a length of the plurality of probes protruding from the guide plate module is longer than a length of the optical fiber protruding from the guide plate module.

In one preferred embodiment of the present application, the optical fiber further includes an optical fiber head, wherein the optical fiber head passes through the second guide plate through hole.

In one preferred embodiment of the present application, a first adhesive layer is coated on an inside of the first guide plate through hole.

In one preferred embodiment of the present application, a second adhesive layer is coated on an inside of the second guide plate through hole.

In one preferred embodiment of the present application, the optical fiber is positioned around the plurality of probes.

In one preferred embodiment of the present application, a third guide plate is disposed between the first guide plate and the second guide plate, wherein the third guide plate includes a plurality of third guide plate through holes for the optical fiber and the plurality of probes to pass through.

The optoelectronic integrated circuit testing device of the present application has at least the following advantages:

1. The optoelectronic integrated circuit testing device of the present application utilizes the receiving interface module and the automated testing equipment which are up and down disposed to extend the optical fiber from the automated testing equipment, and a plurality of probes from the receiving interface module. The optical fiber passes through the receiving interface module and the guide plate module, and the plurality of probes pass through the guide plate module. By calibrating the optical fiber and the plurality of probes at the same time to achieve integrated measurement of photoelectric signals of the optoelectronic integrated circuit test device, the present application achieves the effect of simplifying optoelectronic integrated circuit testing.

2. The optoelectronic integrated circuit testing device of the present application uses a guide plate module including a first guide plate and a second guide plate to position the optical fiber and the plurality of probes, wherein a probe elastic portion is arranged between the first guide plate and the second guide plate. The optoelectronic integrated circuit testing device can position the optical fiber and the optoelectronic integrated circuit within an elastic range of the probe elastic portions of the plurality of probes when measuring the optoelectronic signal of the optoelectronic integrated circuit, after the probe contacts the optoelectronic integrated circuit, thereby solving the problem that the optical communication signal is inaccurate when the optoelectronic integrated circuit testing device receives the circuit signal, which makes it difficult to test the optoelectronic integrated circuit accurately.

3. The optoelectronic integrated circuit testing device of the present application concentrates the transmission of electrical signals by positioning optical fibers around a plurality of probes, and the length of the probes protruding from the guide plate module is longer than the length of the optical fiber protruding from the guide plate module. Moreover, the plurality of second guide plate through hole are coated with an adhesive layer, thereby improving an accuracy of optical fiber calibration and solving the problem of difficulty in calibrating optical communication signals for photoelectric signal measurement.

From the above three points, it can be seen that the optoelectronic integrated circuit testing device of the present application can integrate photoelectric signal measurement, effectively avoid optical communication signal misalignment when the optoelectronic integrated circuit testing device receives the circuit signal, and solve the problem of testing cost and manufacturing costs remain high of the optoelectronic integrated circuit.

### BRIEF DESCRIPTION OF DRAWINGS

In order to explain the technical solutions in the embodiments of the present application more clearly, the accompanying figures required in the description of the embodiments will be briefly introduced below:

FIG. 1 is a schematic diagram of an optoelectronic integrated circuit testing device according to one embodiment of the present application.

FIG. 2 is a schematic diagram of an optoelectronic integrated circuit testing device according to yet another embodiment of the present application.

FIG. 3 is a schematic diagram of a guide plate according to one embodiment of the present application.

FIG. 4 is a schematic diagram of a guide plate module according to one embodiment of the present application.

FIG. 5 is a schematic diagram of a guide plate module according to another embodiment of the present application.

FIG. 6 is a schematic diagram of a guide plate module according to yet another embodiment of the present application.

FIG. 7 is a schematic diagram of a distribution of a plurality of probes and a plurality of optical fibers on the guide plate module according to one embodiment of the present application.

FIG. 8 is a schematic diagram of a guide plate module according to yet another embodiment of the present application.

### DETAILED DESCRIPTION OF PREFERRED EMBODIMENTS

In order to make the above and other objects, features, and advantages of the present application more obvious and easy to understand, preferred embodiments of the present application will be cited in the following and described in detail with reference to the attached figures.

As used herein, unless otherwise stated, the ordinal adjectives “first,” “second,” “third,” etc., used herein to describe common objects, merely indicate the different aspects of the similar objects being mentioned, and are not intended to imply that the objects so described must be in a provided order in time, space, arrangement or in any other way.

The present application provides a testing device for testing the electrical properties and optical communication characteristics of optoelectronic integrated circuits. In some embodiments provided in the present application, the optoelectronic integrated circuit measured by the optoelectronic integrated circuit testing device 1 includes an electronic integrated circuit (EIC) of an electrical arithmetic processor and a photonic integrated circuit (PIC) responsible for electro-optical conversion. The optoelectronic integrated circuit tested by the optoelectronic integrated circuit testing device 1 of the present application also includes co-packaged optics (CPO) that integrate electronic integrated circuits and photonic integrated circuits in a single encapsulation structure and have a stacked structure, or other optoelectronic integrated circuits used for external transmission of optical communication signals and electrical signals. The measured optoelectronic integrated circuit can pass through at least one light detection component, a light source module, and a plurality of active components and passive components, such as filters or multiplex structures, optical power distribution structures, optical fiber input and output structures, and light modulation structures, or other optical active and passive components known to those skilled in the art to transmit optical communication signals.

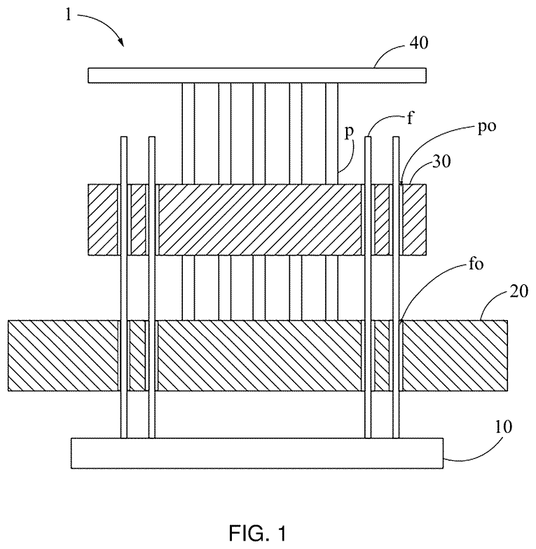

Referring to FIG. 1, the figure is a schematic diagram of an optoelectronic integrated circuit testing device according to one embodiment of the present application. The embodiment of the present application provides an optoelectronic integrated circuit testing device 1 for testing the optoelectronic integrated circuit 40, including automated testing equipment (ATE) 10, a plurality of optical fibers f, a receiving interface module 20, a guide plate module 30, and a plurality of probes p. Each optical fiber f is connected to the automated testing equipment 10 respectively. The receiving interface module 20 is positioned above the automated testing equipment 10, and the receiving interface module 20 is provided with a plurality of optical fiber through holes fo for the optical fibers f to pass through. Each probe p is connected to the receiving interface module 20. The guide plate module 30 is disposed on the receiving interface module 20, and the plurality of probes p and the plurality of optical fibers f pass through the guide plate module 30. The plurality of probes p pressed against the optoelectronic integrated circuit 40, and the plurality of optical fibers f are respectively used to receive optical communication signals transmitted from the optoelectronic integrated circuit 40. The optoelectronic integrated circuit testing device 1 of the present application transmits electrical signals and optical communication signals to the optoelectronic integrated circuit 40 through the plurality of probes p and the plurality of optical fibers f, and receiving electrical signals and optical communication signals transmitted from the optoelectronic integrated circuit 40 through the plurality of probes p and the plurality of optical fibers f.

A first connector (not shown) for connecting the automated testing equipment 10 and the receiving interface module 20 is provided between the automated testing equipment 10 and the receiving interface module 20. A second connector for connecting the receiving interface module 20 and the guide plate module 30 is provided between the receiving interface module 20 and the guide plate module 30. The optoelectronic integrated circuit testing device 1 of the present application uses the first connector and the second connector (not shown) to form a stable probe head (P/H) includes the automated testing equipment 10, the receiving interface module 20, and the guide plate module 30.

In one embodiment provided by the present application, the first support member is configured to have a conductor for transmitting electrical signals to transmit signals received and output by the automated testing equipment 10 and the receiving interface module 20.

It should also be noted that in yet another embodiment of the present application, the number of optical fibers f in the optoelectronic integrated circuit testing device 1 can be designed to have only one in conjunction with the measurement product to further improve the photoelectric measurement performance and product applicable fields of optoelectronic integrated circuit testing equipment.

The different configurations of the optoelectronic integrated circuit testing device 1 of the present application will be described in detail below.

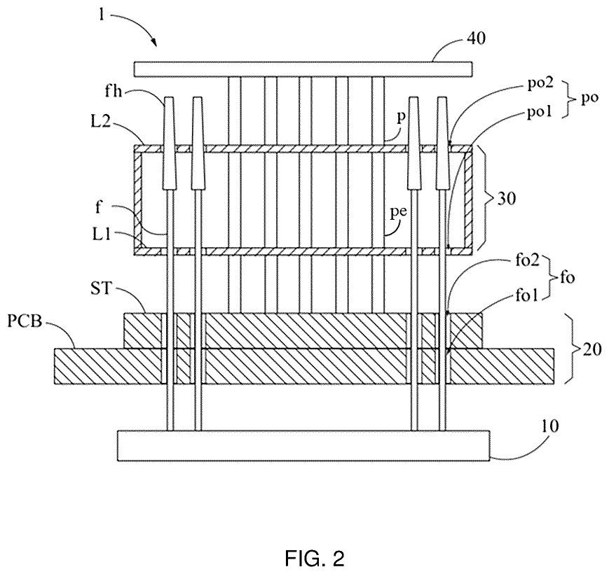

Referring to FIG. 2, which is a schematic diagram of an optoelectronic integrated circuit testing device according to yet another embodiment of the present application. In this embodiment, the guide plate module 30 includes a first guide plate L1 and a second guide plate L2. The first guide plate L1 is disposed above the receiving interface module 20. The first guide plate L1 includes a plurality of first guide plate through holes po1 for respectively passing through at least one of a plurality of optical fibers f or at least one of a plurality of probes p. The second guide plate L2 is disposed above the first guide plate L1. The second guide plate L2 includes a plurality of second guide plate through holes po2 for respectively passing through at least one of the plurality of optical fibers f or at least one of the plurality of probes p. A spacer is also provided between the first guide plate L1 and the second guide plate L2 to support the first guide plate L1 and the second guide plate L2 to form the guide plate module 30. In some embodiments, the spacers are positioned around the first guide plate L1 and the second guide plate L2 respectively, and are configured to expand and contract synchronously. That is, through the arrangement of the spacers, the second guide plate L2 can keep moving at an equal distance from the first guide plate L1, at this time, the first guide plate L1 does not move relative to the plurality of optical fibers f and the plurality of probes p.

In one embodiment provided by the present application, the receiving interface module 20 includes a printed circuit board PCB and a space transformer ST. The printed circuit board PCB is disposed on the automated testing equipment 10. The printed circuit board PCB is provided with a plurality of first optical fiber through holes fo1 for respectively passing through at least one of the plurality of optical fibers f. The space converter ST is disposed on the printed circuit board PCB. The space converter device ST is provided with a plurality of second optical fiber through holes fo2 for respectively passing through at least one of the plurality of optical fibers f. Each probe p is connected to the space transformer ST, and each optical fiber through hole fo respectively includes a first optical fiber through hole fo1 and a second optical fiber through hole fo2.

In particular, in one embodiment provided by the present application, the part where each probe p passes through the guide plate module 30 is provided with a probe elastic portion pe. The probe elastic portion pe is positioned between the first guide plate L1 and the second guide plate L2 when the guide plate module 30 is composed of the first guide plate L1 and the second guide plate L2. The probe elastic portion pe may be configured to be mixed with a flexible material, or the probe elastic portion pe may have a cut, a recessed, or a curved structure compared to the probe p, so that the region of the probe p having the probe elastic portion pe can be compressed up and down without being damaged.

In one embodiment provided by the present application, the plurality of optical fibers f also includes optical fiber heads fh respectively. The optical fiber heads fh pass through the second guide plate through hole po2, and the bottom of the optical fiber heads fh is positioned between the first guide plate L1 and the second guide plate L2. A moving range of the first guide plate L1 relative to the optical fiber f does not exceed a range covered by the optical fiber head fh when the first guide plate L1 moves relative to the optical fiber head fh. In some embodiments, the optical fiber head fh can also be used to limit the movement range of the first guide plate L1. It should be noted that although the optical fiber head fh shown in FIG. 2 has a substantially conical structure, the optical fiber head fh provided by the present application is also made of other materials for coating the optical fiber f that are commonly known to those skilled in the art, will not be explained in detail here. Types of optical fiber f include optical fiber pins, gradient index lenses, photo couplers, or other optical fiber components known to those skilled in the art.

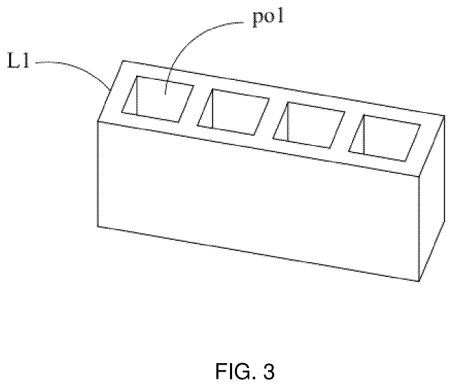

Referring to FIG. 3, the figure is a schematic diagram of a guide plate according to one embodiment of the present application. The first guide plate L1 includes a plurality of first guide plate through holes po1, and a distance between each first guide plate through hole po1 ranges from 1 μm to 500 μm. In some embodiments, the first guide plate through holes po1 may not be arranged at equal intervals. For example, a distance between the first guide plate through holes po1 for the optical fiber f to pass through is greater than a distance between the first guide plate through hole po1 for the optical fiber f to pass through and the first guide plate through hole po1 for the probe p to pass through. The distance between the first guide plate through hole po1 for the optical fiber f to pass through and the first guide plate through hole po1 for the probe p to pass through is greater than a distance between the first guide plate through holes po1 for the probe p to pass through. In addition to the first guide plate L1, the second guide plate L2, or the third guide plate L3 mentioned in the following paragraphs, or other newly installed guide plates can also be in the form of the first guide plate L1 as shown in FIG. 3. Preferably, the number of guide plates provided in the guide plate module 30 may be 2 to 4. The following will continue to describe the structure of the guide plate module 30 in different embodiments of the present application.

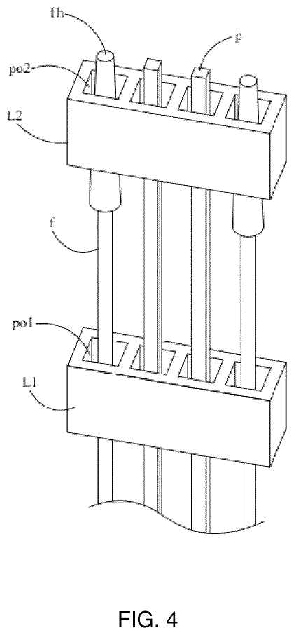

Referring to FIGS. 4 to 8, these figures are respectively schematic diagrams of the guide plate module provided by the present application. In the embodiment shown in FIG. 4, the guide plate module 30 is composed of a first guide plate L1 and a second guide plate L2 that support the optical fiber f passing through the first guide plate L1 and the second guide plate L2. In some embodiments, a distance between the first guide plate L1 and the second guide plate L2 ranges from 300 μm to 2 mm, a thickness of the first guide plate L1 and the second guide plate L2 ranges from 50 μm to 800 μm, a length of the probe p protruding from the second guide plate L2 is longer than a length of the fiber f protruding from the guide plate module 30.

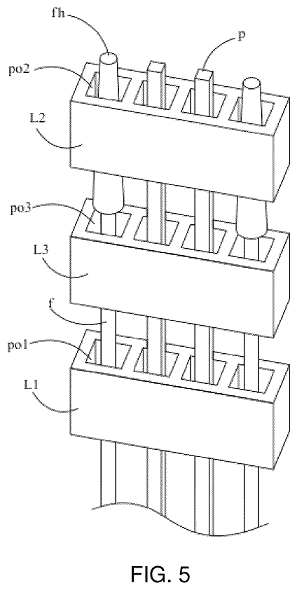

Referring to FIG. 5, in the embodiment disclosed in FIG. 5, the guide plate module 30 is composed of the first guide plate L1, the second guide plate L2, and the third guide plate L3 positioned between the first guide plate L1 and the second guide plate L2. The third guide plate L3 includes a plurality of third guide plate through holes po3 for respectively passing through at least one of a plurality of optical fibers f or at least one of a plurality of probes p. In this embodiment, a bottom of the optical fiber head fh is positioned between the second guide plate L2 and the third guide plate L3. A moving range of the first guide plate L1 does not exceed a range of the optical fiber head fh covering the optical fiber f when the first guide plate L1 moves relative to the optical fiber f and the probe p. The probe elastic portion pe is positioned on the portion of the probe p between the second guide plate L2 and the third guide plate L3 when the probe p includes the probe elastic portion pe and the guide plate module 30 is composed of the first guide plate L1, the second guide plate L2, and the third guide plate L3. At this time, only the second guide plate L2 moves relative to the probe p and the optical fiber f. A length of the probe p protruding from the guide plate module 30 is longer than a length of the optical fiber f protruding from the guide plate module 30 when the probe elastic portion pe is stretched. The aforementioned spacers are also provided between the second guide plate L2 and the third guide plate L3, and between the third guide plate L3 and the first guide plate L1, to support the first guide plate L1, the second guide plate L2, and the third guide plate L3. Or, in some embodiments, the spacers are used to maintain equidistant movement of the first guide plate L1 and the second guide plate L2, and to maintain equidistant movement of the second guide plate L2 and the third guide plate L3.

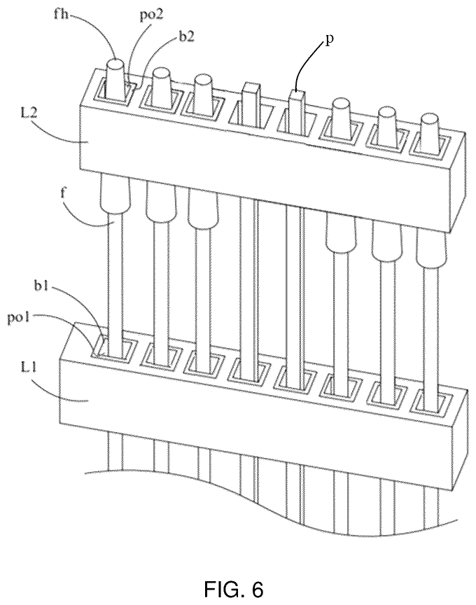

Referring to FIG. 6, the difference between the embodiment disclosed in FIG. 6 and the embodiment disclosed in FIG. 4 is that more than one optical fiber f arranged adjacent to one side of the probe p. That is, within one row of the same guide plate, the number of transmission channels for optical communication signals is greater than the number of transmission channels for electrical signals, thereby reducing the impact of electrical signal transmission on optical communication signal transmission. It should be noted that FIG. 6 only illustrates a single row of guide plate through holes for clear description. However, the guide plate of the present application can be composed of multiple rows of guide plate layouts as shown in FIG. 6 to form an array-type guide plate. However, in the same guide plate, the total number of probes p is greater than the total number of optical fibers f.

Continuing to refer to FIG. 6, a first adhesive layer b1 is also coated on an inside of the first guide plate through hole po1, and a second adhesive layer b2 is also coated on an inside of the second guide plate through hole po2. In some embodiments, the first adhesive layer b1 is coated on the inside of each first guide plate through hole po1 to fix each optical fiber f and probe p passing through the first guide plate through hole po1, and the second adhesive layer b2 is only coated on the inside of the second guide plate through hole po2 for passing the optical fiber f to fix each optical fiber passing through the second guide plate through hole po2. The probe p positioned at the center of the guide plate can move relative to the second guide plate L2 to accurately measure the electrical signals and optical communication signals of the optoelectronic integrated circuit 40. In this embodiment, the spacer between the first guide plate L1 and the second guide plate L2 does not expand or contract, and only the probe p moves relative to the second guide plate L2. At this time, the length of the probe p protruding from the guide plate module 30 is longer than the length of the optical fiber f protruding from the guide plate module 30.

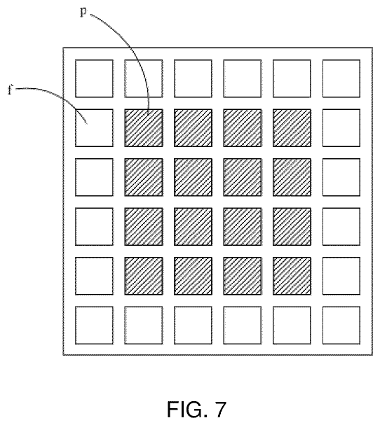

Referring to FIG. 7, the figure is a schematic diagram of the distribution of a plurality of probes and a plurality of optical fibers on the guide plate module according to one embodiment of the present application. The plurality of optical fibers f are positioned around the plurality of probes p. The plurality of probes p are arranged in an array and concentrated in the center of the guide plate. The plurality of optical fibers f are arranged in an array around the plurality of probes p. At this time, the electrical signals transmitted by the plurality of probes p are concentrated in the center of the guide plate to prevent the optical communication signals transmitted by the optical fiber f from being affected by the electrical signals transmitted by the probes p. It should be noted that FIG. 7 is intended to illustrate the layout of the guide plate through holes po of the guide plate module 30 when viewed from top to bottom. The plurality of optical fibers f and the plurality of probes p are arranged in an array on the guide plate module. When the guide plate module 30 is composed of more than two guide plates, the layout of each guide plate is the same, and the guide plate through holes passing through the plurality of optical fibers and the guide plate through holes passing through the plurality of probes are respectively aligned with other guide plates on the upper/lower layer. Regarding the spacing of the guide plate through holes of each guide plate in the guide plate module 30 and the arrangement of the adhesive layer, please refer to the foregoing description, and the description will not be repeated here.

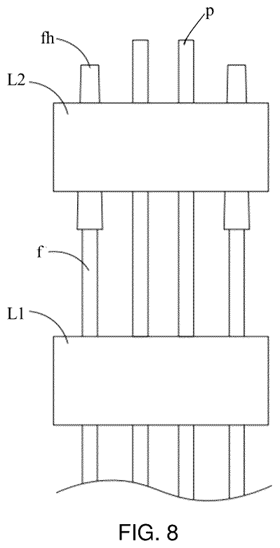

Referring to FIG. 8, the figure is a schematic diagram of a guide plate module according to yet another embodiment of the present application. In this embodiment, a length of the probe p protruding from the guide plate module 30 is longer than a length of the optical fiber f protruding from the guide plate module 30. A range of difference between the length of the probe p protruding from the guide plate module 30 and the length of the optical fiber f protruding from the guide plate module 30 is from 5 μm to 400 μm. Preferably, the length of the probe p protruding from the guide plate module 30 is longer than the length of the optical fiber f protruding from the guide plate module 30, ranges from 10 μm to 400 μm. The optical fiber f and the optoelectronic integrated circuit 40 can still maintain a distance ranges from 10 μm to 400 μm when the probe p is pressed against the optoelectronic integrated circuit 40. In some embodiments, a distance range between the optical fiber f and the optoelectronic integrated circuit 40 is a range in which the length of the probe p protruding from the guide plate module 30 longer than the length of the optical fiber f protruding from the guide plate module 30 minus an elasticity range of the probe elasticity pe, wherein the optical fiber f is not in contact with the optoelectronic integrated circuit 40.

The optoelectronic integrated circuit testing device of the present application has at least the following advantages:

1. The optoelectronic integrated circuit testing device of the present application utilizes a receiving interface module and automated testing equipment arranged in parallel to extend a plurality of optical fibers from the automated testing equipment, and a plurality of probes to extend from the receiving interface module. A plurality of optical fibers pass through the receiving interface module and the guide plate module, and a plurality of probes pass through the guide plate module. The above-mentioned module is used to simultaneously calibrate a plurality of optical fibers and a plurality of probes to achieve the effect of integrating the photoelectric signal measurement of the optoelectronic integrated circuit test device and simplifying the test of the optoelectronic integrated circuit.

2. The optoelectronic integrated circuit testing device of the present application uses a guide plate module including a first guide plate and a second guide plate to position the optical fiber and the probe, and the probe elastic portion is arranged between the first guide plate and the second guide plate. The optoelectronic integrated circuit testing device can position the optical fiber and the optoelectronic integrated circuit within the elastic range of the probe elastic portion when measuring the optoelectronic signal of the optoelectronic integrated circuit, after the probe contacts the optoelectronic integrated circuit, thereby solving the problem that the optical communication signal is inaccurate causes difficult to test the optoelectronic integrated circuit accurately when the optoelectronic integrated circuit testing device receives the circuit signal.

3. The optoelectronic integrated circuit testing device of the present application positions a plurality of optical fibers around a plurality of probes, and the length of the probes protruding from the guide plate module is longer than the length of the plurality of optical fibers protruding from the guide plate module. In addition, the through holes of the guide plate are coated with an adhesive layer, which can improve the accuracy of optical fiber calibration and solve the problem of difficulty in calibrating optical communication signals for photoelectric signal measurement.

From the above three points, it can be seen that the optoelectronic integrated circuit testing device of the present application can integrate photoelectric signal measurement and effectively prevent the optical communication signal from being inaccurate when the optoelectronic integrated circuit testing device receives the circuit signal, and solve the problem of high testing cost and manufacturing cost of optoelectronic integrated circuits.

The above are only preferred embodiments of the present application. It should be pointed out that those skilled in the art can make several improvements and modifications without departing from the principles of the present application. These improvements and modifications should also be considered in a protection scope of the present application.

What is claimed is:

1. An optoelectronic integrated circuit testing device configured to test an optoelectronic integrated circuit, comprising:
an automated testing equipment;
an optical fiber connected to the automated testing equipment;
a receiving interface module disposed on the automated testing equipment, and provided with an optical fiber through hole for the optical fiber to pass through;
a plurality of probes, wherein each probe is connected to the receiving interface module; and
a guide plate module disposed on the receiving interface module, wherein the plurality of probes and the optical fiber pass through the guide plate module;
wherein the plurality of probes pressed against the optoelectronic integrated circuit when testing the optoelectronic integrated circuit, and the optical fiber receives optical communication signals transmitted from the optoelectronic integrated circuit.

2. The optoelectronic integrated circuit testing device according to claim 1, wherein the guide plate module comprises:
a first guide plate disposed on the receiving interface module, wherein the first guide plate comprises a plurality of first guide plate through holes for the optical fiber and the plurality of probes to pass through; and
a second guide plate disposed on the first guide plate, wherein the second guide plate comprises a plurality of second guide plate through holes for the optical fiber and the plurality of probes to pass through.

3. The optoelectronic integrated circuit testing device according to claim 1, wherein portions where the plurality of probes pass through the guide plate module are respectively provided with a probe elastic portion.

4. The optoelectronic integrated circuit testing device according to claim 1, wherein the receiving interface module comprises:
a printed circuit board provided on the automated testing equipment, wherein the printed circuit board is provided with a first optical fiber through hole for the optical fiber to pass through; and
a space converter provided on the printed circuit board, wherein the space converter is provided with a second optical fiber through hole for the optical fiber to pass through;
wherein each probe connected to the space converter, and each optical fiber through hole comprises the first optical fiber through hole and the second optical fiber through hole respectively.

5. The optoelectronic integrated circuit testing device according to claim 1, wherein a length of the plurality of probes protruding from the guide plate module is longer than a length of the optical fiber protruding from the guide plate module.

6. The optoelectronic integrated circuit testing device according to claim 2, wherein the optical fiber further comprises an optical fiber head, and wherein the optical fiber head passes through the second guide plate through hole.

7. The optoelectronic integrated circuit testing device according to claim 2, wherein a first adhesive layer is coated on an inside of the first guide plate through hole.

8. The optoelectronic integrated circuit testing device according to claim 2, wherein a second adhesive layer is coated on an inside of the second guide plate through hole.

9. The optoelectronic integrated circuit testing device according to claim 1, wherein the optical fiber is positioned around the plurality of probes.

10. The optoelectronic integrated circuit testing device according to claim 2, wherein a third guide plate is disposed between the first guide plate and the second guide plate, and wherein the third guide plate comprises a plurality of third guide plate through holes for the optical fiber and the plurality of probes to pass through.
